(19) United States
(12) Patent Application Publication
(10) Pub. No.: US 2025/0176187 A1
(43) Pub. Date: May 29, 2025

(54) MEMORY DEVICE WITH STAIRCASE FREE STRUCTURE AND METHODS FOR FORMING THE SAME

(71) Applicant: Applied Materials, Inc., Santa Clara, CA (US)

(72) Inventors: Ying HUANG, Shanghai (CN); Hailong ZHOU, San Jose, CA (US)

(21) Appl. No.: 18/730,681

(22) PCT Filed: Feb. 24, 2022
(86) PCT No.: PCT/US2022/017609

§ 371 Date: Jul. 19, 2024

(51) Int. Cl. H10B 43/35; H01L 21/311; H10B 41/27; H10B 41/35; H10B 43/27

(52) U.S. Cl. CPC H10B 43/35; H01L 21/31116; H01L 21/31144; H10B 41/27; H10B 41/35; H10B 43/27

(57) ABSTRACT

Embodiments of the disclosure include an apparatus and method of forming a non-volatile memory device that includes positioning a substrate on a surface of a substrate support disposed within a processing region of a processing chamber, delivering a processing gas composition to the processing region, and etching a plurality of alternating layers formed over a surface of the substrate. The substrate includes a hard mask layer disposed over a plurality of alternating layers, which include a first layer and a second layer that are stacked in a vertical direction. The hard mask layer includes an array of mask openings formed therein, which are aligned in a first pitch direction, and have a pitch length in the first pitch direction between adjacent mask openings in the array of openings. The substrate further includes a first photoresist layer disposed over the hard mask layer and over two or more of the mask openings, and includes an opening that has an exposed surface. The process of etching the plurality of layers includes forming a plasma in the processing region of the process chamber, wherein the plasma comprises the processing gas composition, and the process of etching the plurality of alternating layers etches the first photoresist layer so that a surface of the opening in the first photoresist layer serially exposes each of the mask openings in the array of mask openings during the etching process, and causes portions of the alternating layers disposed below the serially exposed mask openings to form patterned openings that each have a differing depth within the alternating layers.

### BACKGROUND

### Field

The present disclosure generally relate to memory devices, and methods of manufacturing the same, and more particularly, to device structures and methods of forming three-dimensional (3D) NAND memory devices.

### Description of the Related Art

Memory devices are an essential component in digital electronic devices that are being developed today. As processing speeds of electronic devices increase, the memory capacity of a memory device that is used in conjunction with the electronic device's processor also needs to be increased, and at the same time there is a need for smaller memory devices to meet the market place's desire to create smaller electronic devices in which the memory device is positioned within.

A three-dimensional (3D) NAND memory has been propose that is a transition from a two-dimensional NAND memory structure to a three-dimensional NAND memory structure. FIG. 1 is a simplified schematic example of a conventional 3D NAND memory structure 100. The 3D NAND memory structure includes a channel structure 117 that is oriented in a vertical direction, such that the channel structure 117 is oriented perpendicular (e.g., −Z-direction) to a major surface of the substrate 101 that includes an etch stop layer 102 and a common source line layer (CSL) 103 disposed thereon. The top of the vertical channel layer structure 117 includes a plurality of bit lines 118. The stacked layers are configured in stacked layer pairs 120 that each include a dielectric layer 116 and a word line layer 115. In this configuration, the word line layers 115 (e.g., four layers shown in FIG. 1) are stacked in the direction that is perpendicular to the major surface of the substrate to form a string of transistors that each include a portion of one of the channel layer structures 117. At an end of each word line layer 115 is a staircase-like structure 110. In the staircase-like structure 110, one or more conductive columns 114 are used to connect the word line layer 115 to an external control circuit by use of connecting element lines 113. In this way, in the 3D NAND memory structure, a transistor may be fabricated in a vertical direction, so that a memory capacity may be easily increased by stacking additional layers.

However, the staircase-like structures 110, which are formed on two opposing edges of the 3D NAND memory structure 100, required a large two-dimensional area (i.e., X-Z plane) to connect all of the word line layers 115 to external elements outside of the 3D NAND device. The large two-dimensional area has a lateral width 112 and a height 125, which limits the number of NAND devices that can be formed in the lateral direction (i.e., X-direction) for a desired lateral 3D NAND size. The lateral width 112 of the staircase-like structure 110 is limited by a minimum pitch 111 that is required to be used between the conductive columns 114 to assure that the patterning process used to define the vertically etched openings that define the position of the conductive columns 114 will reliably land on an exposed portion of the word line layers 115 within each step of the staircase-like structures 110. Moreover, the manufacturing processes used to form the staircase-like structures 110 are overly complex, which reduces device yield and greatly increase the memory cost. The manufacturing processes used to form a typical staircase-like structure 110 requires the completion of a repetitive sequence of steps that require at a minimum a first lithography (Litho) step that is then followed by a second plasma etching step (Etch) for each of the steps in the staircase-like structure 110. In one example, a staircase-like structure 110 that includes four staircase steps, as shown in FIG. 1, will require a Litho-Etch-Litho-Etch-Litho-Etch-Litho-Etch processing sequence to form the four staircase steps in each of the two staircase-like structures 110 illustrated in FIG. 1.

Moreover, plasma etching processes involved in the fabrication of 3D NAND devices are becoming increasingly challenging. Specifically, the staircase contact etch, which is used to form 3D NAND devices, is used to provide access to portions of the cells at the bottom of the NAND stack, and has become increasingly challenging due to the need to form high aspect ratio features having and aspect ratio from 20:1 to 40:1. Etching through high aspect ratio conductive layers intensifies the demands on the etching process, which must be capable of forming openings in layers that are striation free, distortion free, and free of line bending, faceting, and feature clogging. Another challenge in performing a desirable staircase contact etch is to assure that the simultaneous multi-level etching of features that have an aspect ratios ranging from 20:1 to more than 40:1 is done with high selectively to assure that there is negligible loss of the underlying conductive contact materials.

Therefore, there is a need for an improved memory device structure and method of forming the same that solves the problems described above.

### SUMMARY

Embodiments of the disclosure can provide a method of forming a non-volatile memory device, comprising etching a plurality of alternating layers formed over a surface of a substrate, wherein the alternating layers comprises a first layer and a second layer that are stacked in a vertical direction. The method of etching the plurality of layers comprises: delivering a processing gas composition to a processing region of a process chamber; forming a plasma in the processing region of the process chamber, wherein the plasma comprises the processing gas composition; and establishing a voltage waveform at an electrode that is positioned a distance from a substrate supporting surface of a substrate support that is disposed within a processing region of a processing chamber while the plasma is formed over a substrate that is positioned on the substrate supporting surface. The substrate includes: a hard mask layer disposed over the first layer and the second layer of the plurality of alternating layers, wherein the first layer comprises a first material and the second layer comprises a second material that is different from the first material; an array of mask openings formed in the hard mask layer that are aligned in a first pitch direction, and have a pitch length in the first pitch direction between adjacent mask openings in the array of mask openings; and a first photoresist layer disposed over the hard mask layer and over two or more of the mask openings in the array of openings, wherein at least one of the mask openings in the array of openings is exposed to the formed plasma through an opening formed in the first photoresist layer. The processing gas composition being selected so that the formed plasma causes the opening formed in the first photoresist layer to increase in size in the first pitch direction a length that equal to the pitch length during a first time interval, and simultaneously etching through a thickness of the first layer and the second layer during the first time interval.

Embodiments of the disclosure may also provide a method of forming a non-volatile memory device, comprising positioning a substrate on a surface of a substrate support that is disposed within a processing region of a processing chamber, delivering a processing gas composition to the processing region of the process chamber, and etching a plurality of alternating layers formed over the surface of a substrate. The substrate comprises: a hard mask layer disposed over a plurality of alternating layers formed over a surface of the substrate, wherein the alternating layers comprises a first layer and a second layer that are stacked in a vertical direction; an array of mask openings formed in the hard mask layer that are aligned in a first pitch direction, and have a pitch length in the first pitch direction between adjacent mask openings in the array of openings; and a first photoresist layer disposed over the hard mask layer and over two or more of the mask openings in the array of mask openings, and comprises an opening in the first photoresist layer that has an exposed surface, wherein the opening is positioned to expose a first mask opening of the array of mask openings or expose a portion of the hard mask layer adjacent to the first mask opening of the array of mask openings. The process of etching the plurality of layers comprises forming a plasma in the processing region of the process chamber, wherein the plasma comprise the processing gas composition and the plasma is formed over the first photoresist layer and the opening formed therein. The process of etching the plurality of alternating layers causes the first photoresist layer to be etched so that each of the mask openings in the array of mask openings are serially exposed to the formed plasma during the process of etching the plurality of alternating layers, and causes portions of the alternating layers disposed below the serially exposed mask openings to form patterned openings that each have a differing depth within the alternating layers.

Embodiments of the disclosure may also provide a non-volatile memory device, comprising a plurality of alternating layers, wherein the plurality of alternating layers comprise a plurality of stacked layer pairs that each comprise a first layer that comprises a first material and a second layer that comprises a second material which is different from the first material, wherein the plurality of stacked layer pairs are stacked in a first direction and comprise N stacked layer pairs, and N is greater than 10. The non-volatile memory device also includes a plurality of conductive columns, wherein each of the conductive columns are aligned in a first pitch direction, and are separated in the first pitch direction by a pitch length, N−1 of the conductive columns extend through one or more stacked layer pairs, and each of the conductive columns comprises a dielectric layer that is disposed between a conductive material disposed within the conductive column and the layers of the one or more stacked layer pairs that the conductive column extends through, wherein a voltage is applied to the conductive material of the conductive column during the operation of the non-volatile memory device. In some embodiments, the first material and the conductive material each essentially comprise the same material.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 is a simplified schematic example of a conventional 3D NAND memory structure 100.

FIG. 2A is a schematic cross-sectional view of a processing chamber configured to practice one or more of the methods described herein, according to one embodiment.

FIG. 2B illustrates a pulsed voltage (PV) waveform that has been established at a substrate during processing, according to one embodiment.

FIG. 3 is a simplified schematic example of an improved 3D NAND memory structure, according to one or more of the embodiments described herein.

FIG. 4A illustrates a simplified schematic portion of a memory structure that is used to form at least a part of a 3D NAND memory structure, according to one or more of the embodiments described herein.

FIGS. 4B-4O illustrate simplified schematic portions of the memory structure illustrated in FIG. 4A during different portions of the method illustrated in FIG. 5, according to one or more of the embodiments described herein.

FIG. 5 is a flow diagram that illustrates a plurality of activities than can be performed to form at least a part of a 3D NAND memory structure, according to one or more of the embodiments described herein.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

In the following description, details are set forth by way of example to facilitate an understanding of the disclosed subject matter. It should be apparent to a person of ordinary skill in the field, however, that the disclosed implementations are exemplary and not exhaustive of all possible implementations. Thus, it should be understood that reference to the described examples is not intended to limit the scope of the disclosure. Any alterations and further modifications to the described devices, instruments, methods, and any further application of the principles of the present disclosure are fully contemplated as would normally occur to one skilled in the art to which the disclosure relates. In particular, it is fully contemplated that the features, components, and/or steps described with respect to one implementation may be combined with the features, components, and/or steps described with respect to other implementations of the present disclosure. As used herein, the term “about” may refer to a +/−10% variation from the nominal value. It is to be understood that such a variation can be included in any value provided herein.

Embodiments of the disclosure provided herein include an apparatus and method of forming an improved three-dimension (3D) NAND memory structure by use of a less complex processing sequence versus the conventional 3D NAND processing techniques known today. As devices shrink, structures for fabricating efficient and multiple memory cells are needed to maximize the density of memory cells in a memory device. Three-dimension (3D) NAND technology addresses challenges with two-dimensional (2D) NAND technology and stacking memory cells vertically in layers.

Embodiments of the disclosure provided herein include a process sequence that includes the use of an enhanced selectivity etching process that is configured to selectively etch one or more dielectric layers relative to one or more masking layers using a reactive ion etching process. The reactive ion etching process can include a pulsed plasma ion etching process that includes the delivery of a radio frequency (RF) generated RF waveform from an RF generator to one or more electrodes within a processing chamber, and a pulsed-voltage (PV) waveform delivered from one or more pulsed-voltage (PV) generators to the one or more electrodes disposed within a substrate support that is positioned within a processing chamber. Accordingly, pulse voltage technology can enable methods of precisely controlling the plasma ion density and ion energy during plasma processing. It is believed that the precise control of the plasma ion density and ion energy, in combination with the use of a desirable dry etch chemistries, can be used to cause an increase in etch selectivity and improve the process of forming a novel 3D NAND memory structure disclosed herein. Moreover, by use of one or more of the methods described herein, etch selectivity and improved etch process results can be further achieved by the controlled formation of a fluorocarbon-based polymer layer on the exposed conductive materials surfaces during the etching process.

### Plasma Processing Chamber

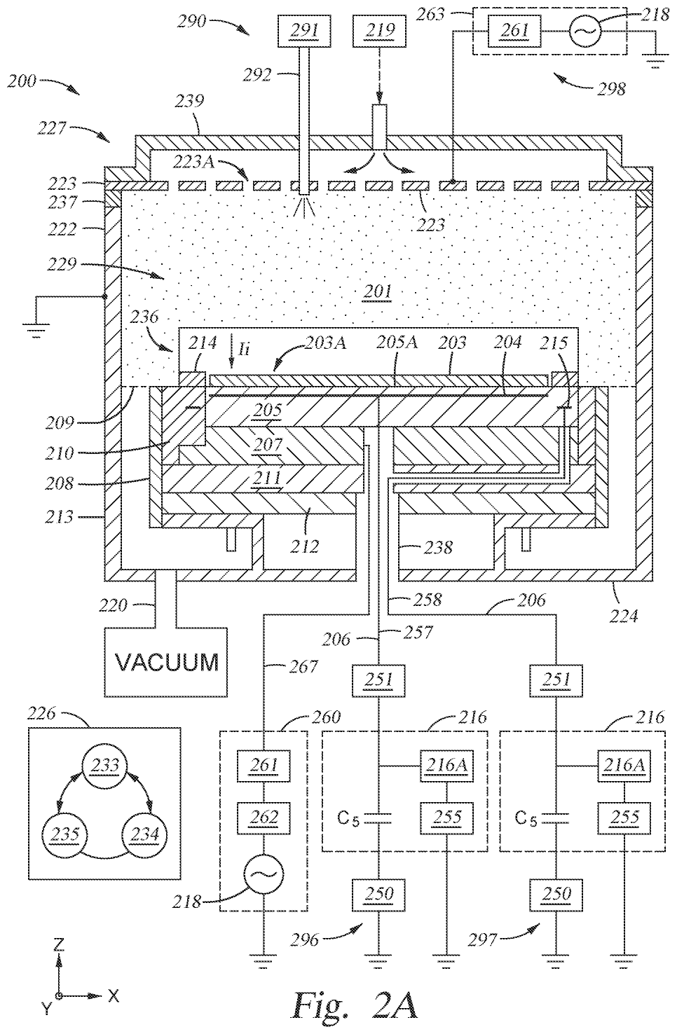

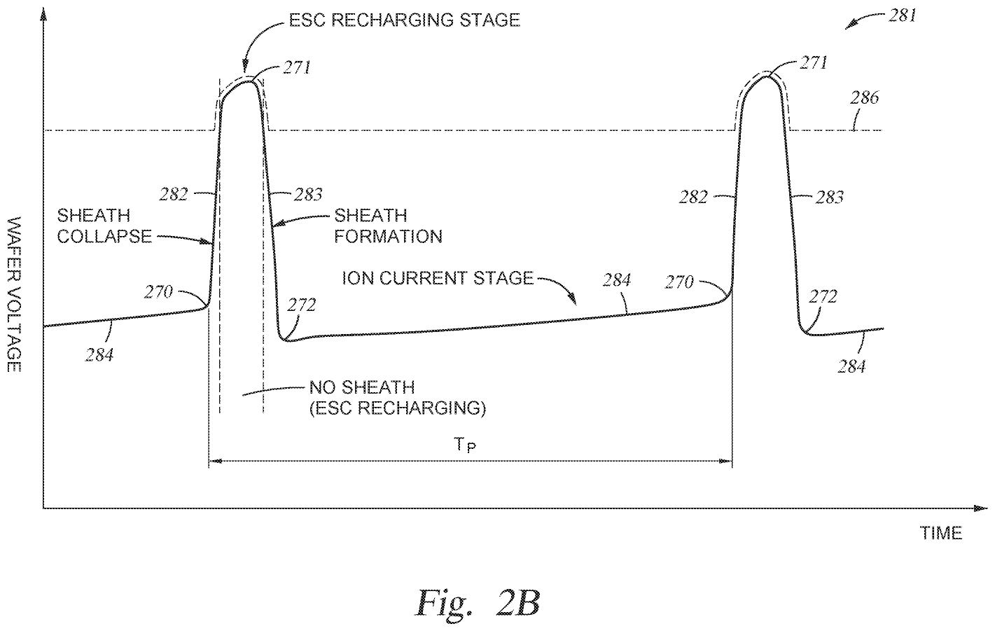

FIG. 2A is a schematic cross-sectional view of a processing chamber 200 configured to practice one or more of the methods of forming the 3D NAND memory structure described herein. In one embodiment, the processing chamber is a plasma processing chamber, such as a reactive ion etch (RIE) plasma chamber. In some embodiments, a plasma is formed in the processing chamber 200 by use of a capacitively coupled plasma (CCP) source, which includes an upper electrode assembly 227 that includes an upper electrode 223, which is disposed in the processing region 229 and faces a substrate support assembly 236. However, in some embodiments, the processing chamber 200 may alternately, or additionally, include an inductively coupled plasma (ICP) source that is configured to form a plasma within the processing region 229.

The processing chamber 200 also includes a chamber body 213 that includes one or more sidewalls 222, and a chamber base 224. The upper electrode 223, the one or more sidewalls 222, and the chamber base 224 together generally define a processing region 229. The one or more sidewalls 222 and chamber base 224 generally include materials that are sized and shaped to form the structural support for the elements of the processing chamber 200, and are configured to withstand the pressures and added energy applied to them while a plasma 201 is generated within a vacuum environment maintained in the processing region 229 of the processing chamber 200 during processing. In one example, the one or more sidewalls 222 and chamber base 224 are formed from a metal, such as aluminum, an aluminum alloy, or a stainless steel. A plurality of holes 223A formed in the upper electrode 223 are used to provide one or more processing gases to the processing region 229 from a processing gas source 219 that is in fluid communication therewith. A substrate 203 is loaded into, and removed from, the processing region 229 through an opening (not shown) in one of the one or more sidewalls 222, which is sealed with a slit valve (not shown) during plasma processing of the substrate 203. Herein, the substrate 203 is transferred to and from a substrate receiving surface 205A of a substrate support 205 using a lift pin system (not shown).

During plasma processing with the processing chamber 200, ions are purposely accelerated towards the substrate 203 by the voltage drop in an electron-repelling sheath that forms over a substrate placed on top of a substrate-support assembly 236. While not intending to be limiting as to the scope of the invention provided herein, the substrate support assembly 236 is often referred to herein as the “cathode assembly” or “cathode”. In some embodiments, the substrate support assembly 236 includes a substrate support 205 and a support base 207. The substrate support 205 can include an electrostatic chuck (ESC) assembly that is configured to chuck (e.g., retain) a substrate 203 on a substrate receiving surface 205A.

In some embodiments, the plasma processing chamber 200 is configured to form a plasma by use of an RF generator assembly 263 that includes an RF generator 218 that is coupled to an RF electrode through a transmission line 267 and an RF matching network 261 (“RF match”). The RF matching network 261 is configured to tune the apparent load to 50Ω to minimize the reflected power and maximize the power delivery efficiency to the complex load 230 formed within the processing region 229 during plasma processing. In some embodiments, the RF electrode includes a metal plate that is positioned parallel to the plasma-facing surface of the substrate 203, such as the support base 207.

As shown in FIG. 2A, the upper electrode assembly 231 includes the upper electrode 223 and a lid plate 239, which are configured to form a showerhead that is configured to evenly distribute one or more gases provided from a processing gas source 219 to the processing region 229 through a plurality of holes 223A formed in the upper electrode 223. The upper electrode assembly 231 is also positioned on, and electrically isolated from, the grounded side wall 222 of the processing chamber 200 by a lid insulator 237. In some embodiments, the upper electrode 223 is electrically coupled to a plasma generator assembly 263, which configured to ignite and maintain a plasma 201 in the processing region 229 by use an RF generator 218 that is coupled to the upper electrode 223 through the RF matching network 261. However, in some embodiments, the plasma generator assembly 263 is not coupled to the upper electrode 223, and in this case the upper electrode 223 may be grounded and the RF power used to form the plasma 201 in the processing region 229 is provided to the biasing electrode 204 and support base 207.

In general, the generated RF waveform (e.g., sinusoidal shaped waveform) provided by the RF generator 218 is configured to establish and maintain a plasma within the processing chamber. The RF waveform can be delivered while pulsed-voltage (PV) waveforms are delivered from a pulsed-voltage (PV) generator 250 during portions of the plasma process and thus create a desirable ion energy distribution function (IEDF) at the surface of the substrate 203 during one or more plasma processing steps performed within the processing chamber. The pulsed-voltage (PV) waveforms provided from a pulsed-voltage (PV) generator 250 are configured to control the sheath voltage across the surface of a substrate 203 positioned on substrate support 205 of the substrate support assembly 236. In some embodiments, one or more pulsed-voltage (PV) generators 250 are configured to establish a pulsed-voltage waveform at one or more biasing electrodes 204 disposed within the substrate support assembly 236. In some embodiments, the one or more biasing electrodes 204 include a chucking electrode that is separated from the substrate 203 by a thin layer of a dielectric material (e.g., 0.1 mm-0.7 mm) formed within the substrate support assembly 236 and optionally an edge control electrode 215 that is disposed within or below an edge ring 214 that surrounds a substrate 203 when the substrate 203 is disposed on the substrate supporting surface 205A of the substrate support assembly 236. In one embodiment, a first PV generator 250 is electrically coupled to a biasing electrode 204 through an RF filter 251 and a transmission line 257, and a second PV generator 250 is electrically coupled to the edge control electrode 215 through an RF filter 251 and a transmission line 258. As will be discussed further below, this PV waveform can be configured to cause a nearly constant sheath voltage (e.g., a difference between the plasma potential and the substrate potential) to be formed for a sizable portion of the PV waveform's pulse period, which corresponds to a single (narrow) peak containing ion energy distribution function (IEDF) of the ions reaching the substrate during this part of the pulse period, which is also referred to herein as the “ion-current phase”. The plasma process(es) disclosed herein can be used to control the interaction of the plasma with a surface of a substrate during processing. In some configurations, the plasma process(es) disclosed herein are used to control the profile of features formed in the surface of the substrate 203 during processing. In some embodiments, the pulsed voltage waveform is established by a PV generator 250 that is electrically coupled to a biasing electrode 204 disposed within a substrate support assembly 236 disposed within a plasma processing chamber 200.

In some embodiments, an RF generator assembly 260 is configured to deliver RF power to the support base 207 disposed proximate to the ESC substrate support 205, and within the substrate support assembly 236. The RF power delivered to the support base 207 is configured to ignite and maintain a processing plasma 201 formed by use of processing gases disposed within the processing region 229. In some embodiments, the support base 207 is an RF electrode that is electrically coupled to an RF generator 218 via an RF matching circuit 261 and a first filter assembly 262, which are both disposed within the RF generator assembly 260. In some embodiments, the plasma generator assembly 260 and RF generator 218 are used to ignite and maintain a processing plasma 201 using the processing gases disposed in the processing region 229 and fields generated by the RF power provided to the support base 207 by the RF generator 218. The processing region 229 is fluidly coupled to one or more dedicated vacuum pumps, through a vacuum outlet 220, which maintain the processing region 229 at sub-atmospheric pressure conditions and evacuate processing and/or other gases, therefrom. A substrate support assembly 236, disposed in the processing region 229, is disposed on a support shaft 238 that is grounded and extends through the chamber base 224. However, in some embodiments, the RF generator assembly 260 is configured to deliver RF power to the biasing electrode 204 disposed in the substrate support 205 versus the support base 207. The RF generator 218 may be configured to provide an RF signal at an RF frequency greater than about 300 KHz to an electrode, such as between about 300 KHz and 60 MHz, or even a frequency in range from about 2 MHz to about 40 MHz.

The substrate support assembly 236, as briefly discussed above, generally includes a substrate support 205 (e.g., ESC substrate support) and support base 207. In some embodiments, the substrate support assembly 236 can additionally include an insulator plate 211 and a ground plate 212, as is discussed further below. The substrate support 205 is thermally coupled to and disposed on the support base 207. In some embodiments, the support base 207 is configured to regulate the temperature of the substrate support 205, and the substrate 203 disposed on the substrate support 205, during substrate processing. In some embodiments, the support base 207 includes one or more cooling channels (not shown) disposed therein that are fluidly coupled to, and in fluid communication with, a coolant source (not shown), such as a refrigerant source or water source having a relatively high electrical resistance. In some embodiments, the substrate support 205 includes a heater (not shown), such as a resistive heating element embedded in the dielectric material thereof. Herein, the support base 207 is formed of a corrosion resistant thermally conductive material, such as a corrosion resistant metal, for example aluminum, an aluminum alloy, or stainless steel and is coupled to the substrate support with an adhesive or by mechanical means.

The support base 207 is electrically isolated from the chamber base 224 by the insulator plate 211, and the ground plate 212 is interposed between the insulator plate 211 and the chamber base 224. In some embodiments, the processing chamber 200 further includes a quartz pipe 210, or collar, that at least partially circumscribes portions of the substrate support assembly 236 to prevent corrosion of the ESC substrate support 205 and, or, the support base 207 from contact with corrosive processing gases or plasma, cleaning gases or plasma, or byproducts thereof. Typically, the quartz pipe 210, the insulator plate 211, and the ground plate 212 are circumscribed by a liner 208. Herein, a plasma screen 209 approximately coplanar with the substrate receiving surface of the ESC substrate support 205 prevents plasma from forming in a volume between the liner 208 and the one or more sidewalls 222.

The substrate support 205 is typically formed of a dielectric material, such as a bulk sintered ceramic material, such as a corrosion resistant metal oxide or metal nitride material, for example aluminum oxide (Al₂O₃), aluminum nitride (AlN), titanium oxide (TiO), titanium nitride (TiN), yttrium oxide (Y₂O₃), mixtures thereof, or combinations thereof. In embodiments herein, the substrate support 205 further includes a biasing electrode 204 embedded in the dielectric material thereof. In one configuration, the biasing electrode 204 is a chucking pole used to secure (chuck) the substrate 203 to a substrate receiving surface 205A of the substrate support 205, also referred to herein as an ESC substrate support, and to bias the substrate 203 with respect to the processing plasma 201 using one or more of the pulsed-voltage biasing schemes described herein. Typically, the biasing electrode 204 is formed of one or more electrically conductive parts, such as one or more metal meshes, foils, plates, or combinations thereof that is spaced apart from the substrate receiving surface 205A of the substrate support 205 by a layer of dielectric material of the substrate support 205. In some embodiments, the biasing electrode 204 is electrically coupled to a bias compensation module 216, which provides a chucking voltage thereto, such as static DC voltage between about −5000 V and about 5000 V, using an electrical conductor, such as the coaxial transmission line 206 (e.g., a coaxial cable). A high voltage module 216 includes bias compensation circuit elements 216A, a DC power supply 255, and a blocking capacitor C₅, which is disposed between the output of a pulsed-voltage waveform generator (PVWG) 250 and the biasing electrode 204.

The processing chamber 200 further includes a controller 226, which is also referred to herein as a processing chamber controller. The controller 226 herein includes a central processing unit (CPU) 233, a memory 234, and support circuits 235. The controller 226 is used to control the process sequence used to process the substrate 203 including the substrate biasing methods described herein. The CPU 233 is a general-purpose computer processor configured for use in an industrial setting for controlling processing chamber and sub-processors related thereto. The memory 234 described herein, which is generally non-volatile memory, may include random access memory, read only memory, floppy or hard disk drive, or other suitable forms of digital storage, local or remote. The support circuits 235 are conventionally coupled to the CPU 133 and comprise cache, clock circuits, input/output subsystems, power supplies, and the like, and combinations thereof. Software instructions (program) and data can be coded and stored within the memory 234 for instructing a processor within the CPU 233. A software program (or computer instructions) readable by CPU 233 in the controller 226 determines which tasks are performable by the components in the processing chamber 200. Preferably, the program, which is readable by CPU 233 in the controller 226, includes code, which, when executed by the processor (CPU 233), performs tasks relating to the monitoring and execution of the electrode biasing scheme described herein. The program will include instructions that are used to control the various hardware and electrical components within the processing chamber 200 to perform the various process tasks and various process sequences used to implement the electrode biasing scheme described herein.

During processing, one or more PV generators within the PV waveform generators 250 of the first PV source assembly 296 and the second PV source assembly 297 establishes a pulsed voltage waveform on a load disposed with the processing chamber 200. The overall control of the delivery of the PV waveform from each of the PV waveform generators 250 is controlled by use of signals provided from the controller 226. In one embodiment, the PV waveform generator 250 is configured to maintain a predetermined, substantially constant positive voltage across its output (i.e., to ground) during regularly recurring time intervals of a predetermined length, by repeatedly closing and opening its internal switch at a predetermined rate. Alternately, in one embodiment, a PV waveform generator 250 maintains a predetermined, substantially constant negative voltage across its output (i.e., to ground) during regularly recurring time intervals of a predetermined length, by repeatedly closing and opening its internal switch at a predetermined rate. Each PV waveform generator 250 will include a PV generator (e.g., DC power supply) and one or more electrical components, such as high repetition rate switches, capacitors (not shown), inductors (not shown), fly back diodes (not shown), power transistors (not shown) and/or resistors (not shown), that are configured to provide a PV waveform to an output port. The PV waveform generator 250 in some cases may be primarily used as a charge injector (current source), and not as a constant voltage source; therefore it is not necessary to impose stringent requirements on the stability of the output voltage, in that it can vary in time even when the switch remains in the closed (On) position.

FIG. 2B illustrates an example of voltage waveform, such as a pulsed voltage (PV) waveform 281 in a series of asymmetric PV waveforms (e.g., non-sinusoidal waveforms) established at the substrate 203 due to an established PV waveform formed at the biasing electrode 204 or edge control electrode 215 by a PV waveform generator 250. The substrate PV waveform 281 is established at the surface of a substrate during processing, and includes a sheath collapse and ESC recharging phase 282 (or for simplicity of discussion the sheath collapse phase 282) that extends between point 270 and point 271 of the illustrative substrate PV waveform 281, a sheath formation phase 283 that extends between point 271 and point 272, and an ion current phase 284 that extends between point 272 and back to the start at point 270 of the next sequentially established pulse voltage waveform. In some embodiments, the sheath collapse phase 282 and sheath formation phase 283 last for a first time interval and the ion current phase 284 lasts for a second time interval, and the first time interval is between about 100 nanoseconds (ns) and about 500 ns, such as between 200 ns and 400 ns, and the second time interval accounts for at least 80% of each cycle of the series of PV waveform, such as between 85% and 90% of each cycle. The plasma potential curve 286 illustrates the local plasma potential during the delivery of the negative pulse waveforms that are established at the biasing electrode 204 and/or edge control electrode 215 by use of one or more PV waveform generators 250, and thus establish the pulsed voltage (PV) waveforms 281 at the substrate 203. By delivering and controlling the PV waveforms provided to the biasing electrode 204 during plasma processing, a desirable ion energy distribution function (IEDF) can be formed, such as a nearly monoenergetic IEDF. The generation and control of the characteristics of the PV waveforms (e.g., peak-to-peak voltage, duty cycle, frequency, etc.) allows for the precise control of the plasma ion density and generated ion energies, and also results in a more controllable fluorinated carbon (CₓF_{y}) based polymer deposition on a conductive material (e.g., W) surface that are often found at the bottom of an etched feature. The formation of the polymer deposition on the conductive material surface will improve the etch selectivity of the dry etch chemistry to the conductive material versus an intervening etched dielectric material. Processing gases that may be suitable for a plasma etching process disclosed herein will generally include fluoride (C₄F₆, C₃F₆, CF₄, NF₃, C₃F₈, C₄F₈, CHF₄, CH₃F, CH₂F₂, SF₆, SiF₄, and WF₆), chloride (HCl, C₂, BCl₃), bromide (Br₂, HBr), or, an oxygen containing gas (e.g., O₃, O₂, CO₂, CO, H₂O, NO, NO₂, N₂O, CO, and the like) and optionally may include an inert gas, such as argon (Ar), xenon (Xe), nitrogen (N₂), krypton (Kr), or helium (He).

In some embodiments, the processing chamber 200 includes one or more sensor assemblies 290, which include a sensor 291 and a probe 292 that are positioned and configured to view a portion of the substrate surface 203A during plasma processing. In one configuration, the probe 292 (e.g., optical fiber) and sensor 291 are positioned to detect a property of a portion of the substrate surface 203A through a portion of the upper electrode assembly 231 by use of an optical emission spectroscopy (OES) technique, such as an interferometric technique. In some embodiments, one or more of the sensor assemblies 290 are configured to detect a property of a portion of the substrate surface, or material disposed thereon, and then provide a signal to the controller 226 so that information regarding the state of the substrate surface, or material thereon, can be used to determine if one or more characteristics of a plasma process being performed in processing chamber needs to be adjusted by the controller 226. The sensor assembly 290 can be configured to detect a status (e.g., relative percent completion) or endpoint of an etching process by detecting an amount of interference and/or the amount of light transmitted to and reflected from the surface of the substrate by the probe 292. In one example, the sensor assembly 290 performs an in-situ measurement of a nitride material's thickness formed in the 3D NAND structure, and/or determine a relative depth of an etched feature formed on a substrate during processing.

### 3D NAND Devices and Processing Sequences

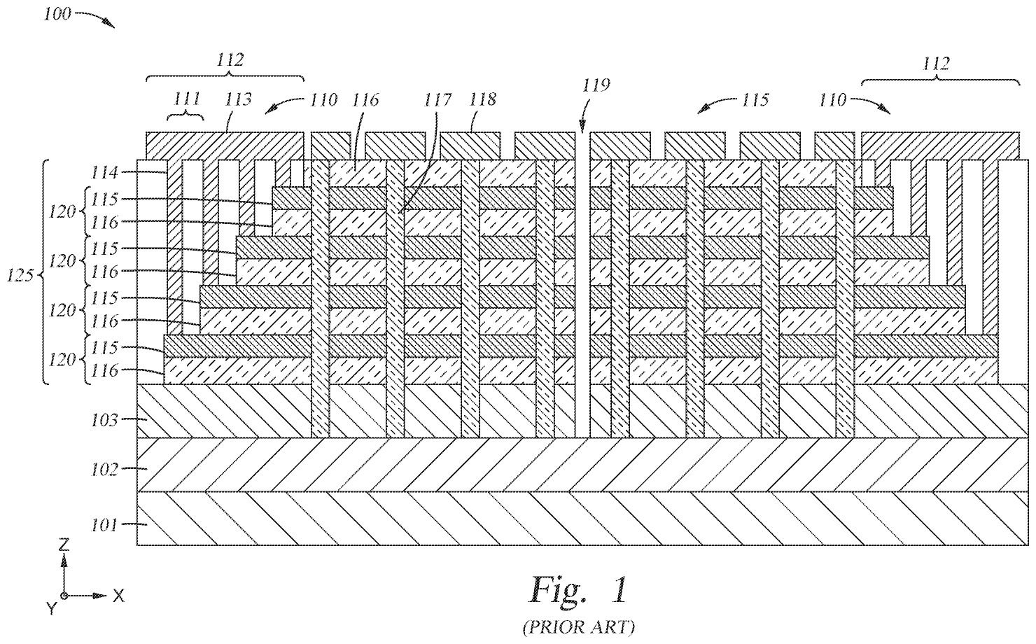

FIG. 3 is a simplified schematic example of an improved 3D NAND memory structure 300. Similar to portions of the 3D NAND memory structure 100 illustrated in FIG. 1, the 3D NAND memory structure 300 includes a channel structure 117 that is oriented perpendicular (e.g., −Z-direction) to a major surface of the substrate 401, which includes an etch stop layer 402 and a common source line layer (CSL) 403 disposed thereon. The top of the vertical channel layer structure 117 of the 3D NAND memory structure 300 includes a plurality of bit lines 118. The 3D NAND memory structure 300 includes a plurality of stacked layers that are configured in stacked layer pairs 320 that each include alternating layers of a dielectric layer 416 and a conductive material 465. The conductive material 465 in the alternating layers form the word line layers 415. The stacked layer pairs 320 are stacked in an alternating fashion in the direction that is perpendicular to the major surface of the substrate 401 to form portions of a string of transistors that each include a portion of one of the channel structures 117. The stacked layer pairs 320 are also sometimes referred to herein as “device stacked layer pairs.” The 3D NAND memory structure 300 desirably does not include the complex and costly staircase-like structures 110 found in conventional 3D NAND memory structures, which are illustrated in FIG. 1. The 3D NAND memory structure 300 alternately includes interconnect regions 310 that are formed over the memory layer stack at the opposing edges of the 3D NAND memory structure 300. Each of the interconnect regions 310 includes a plurality of conductive columns 314 that are formed to desired depths within the memory layer stack, and do not require that formation of the staircase as required by conventional 3D NAND memory structures.

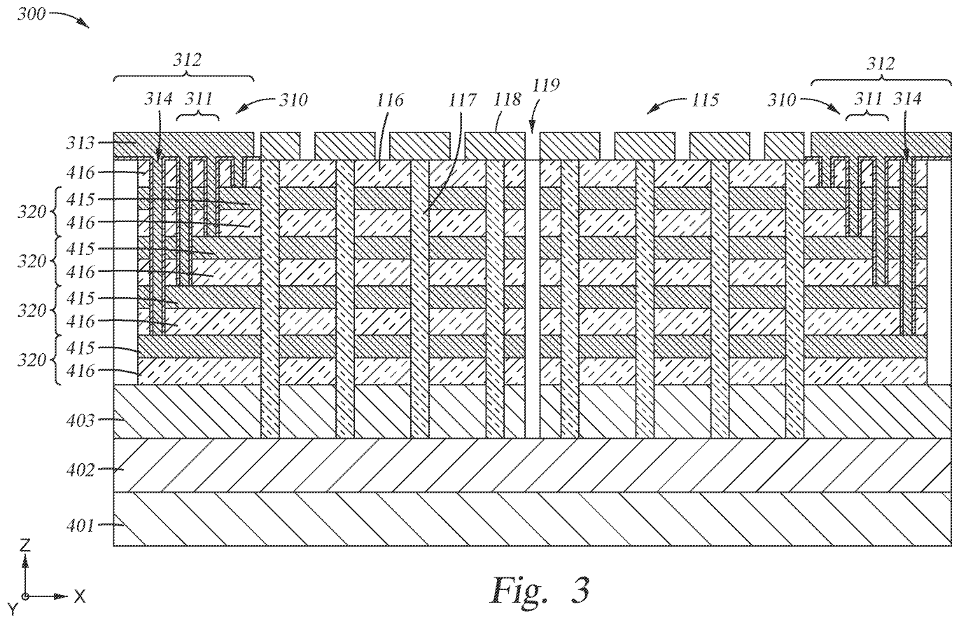

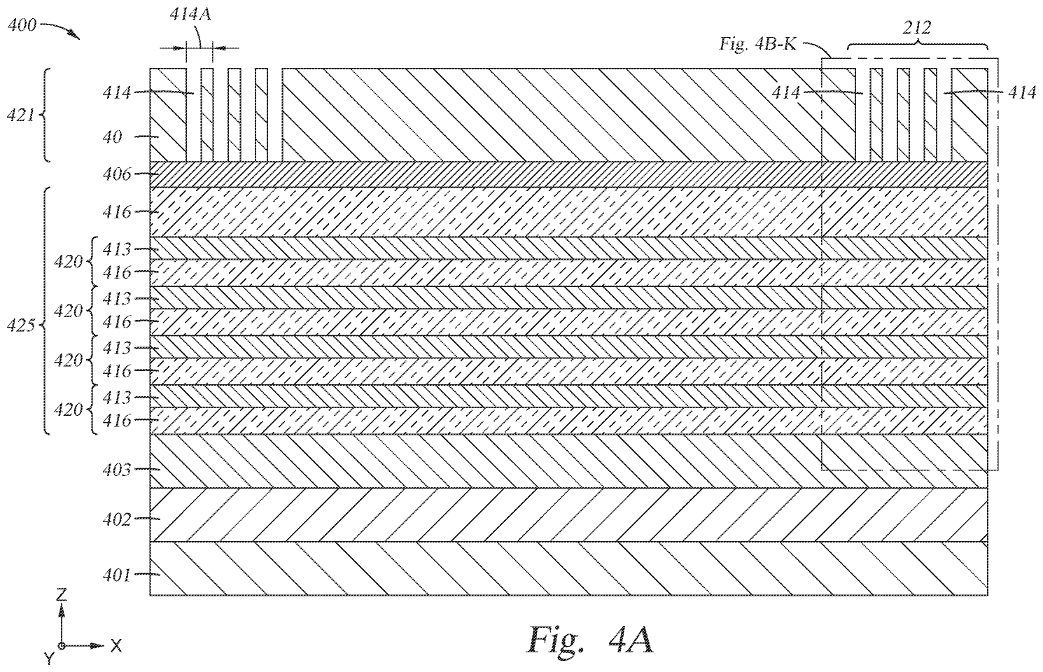

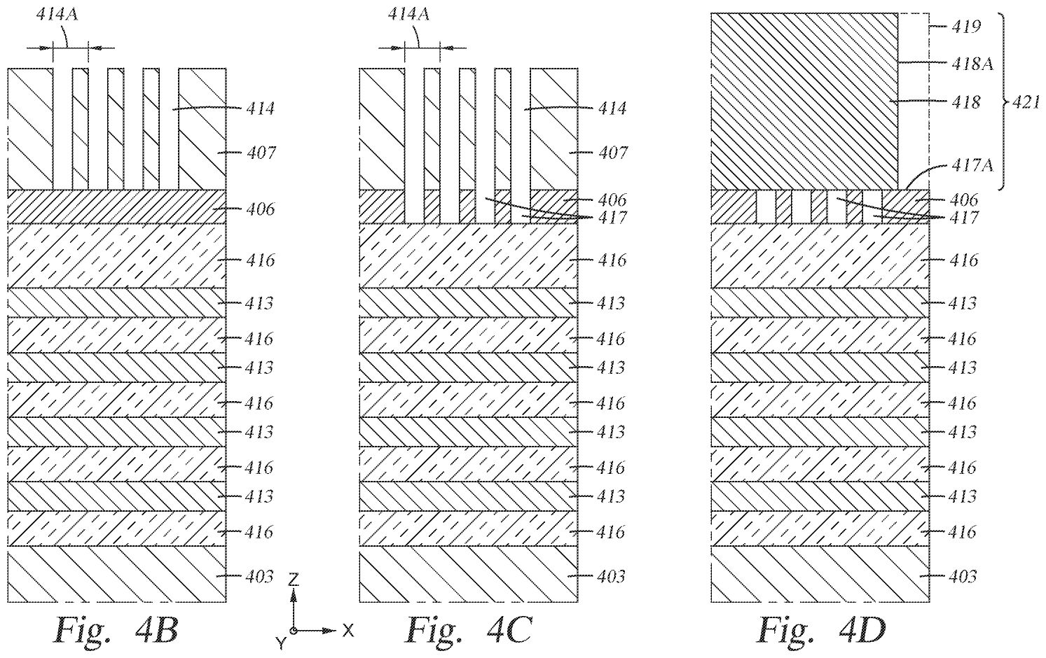

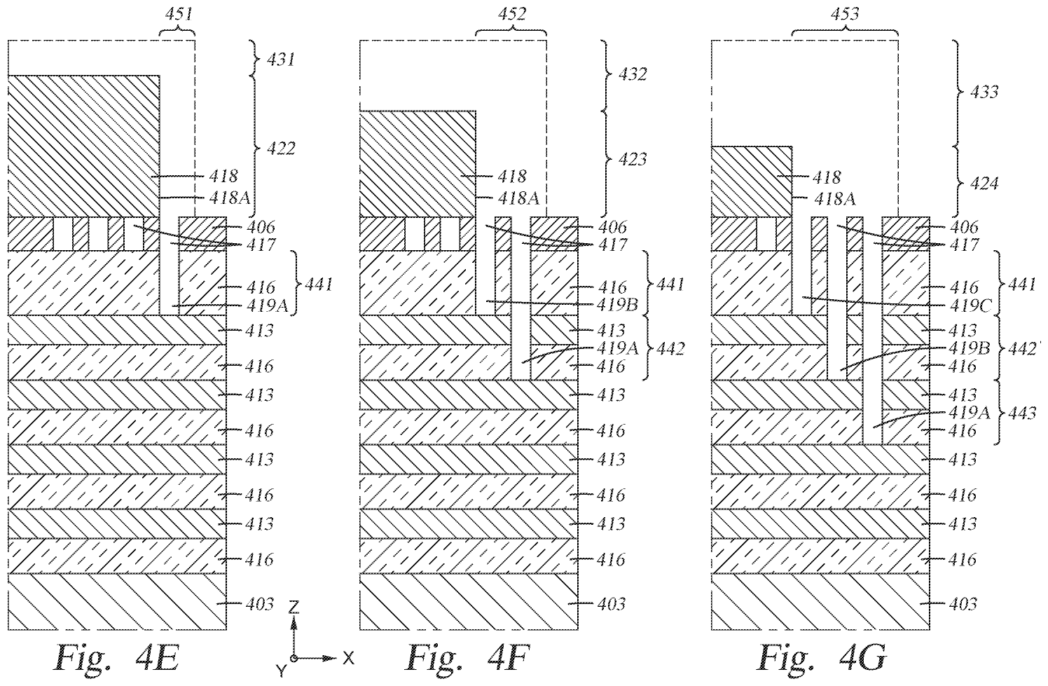

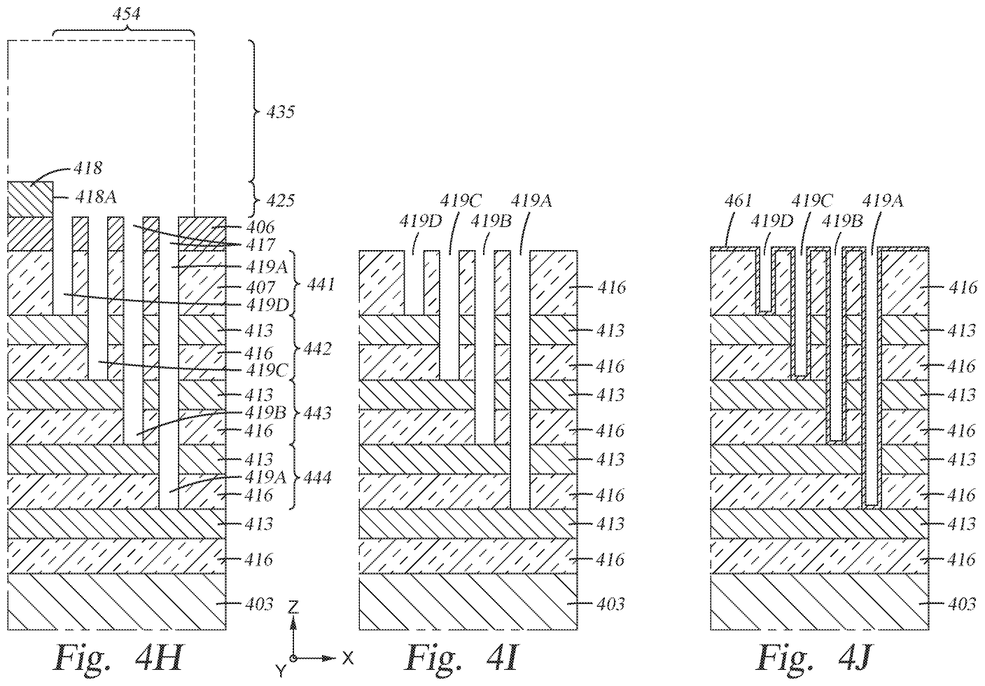

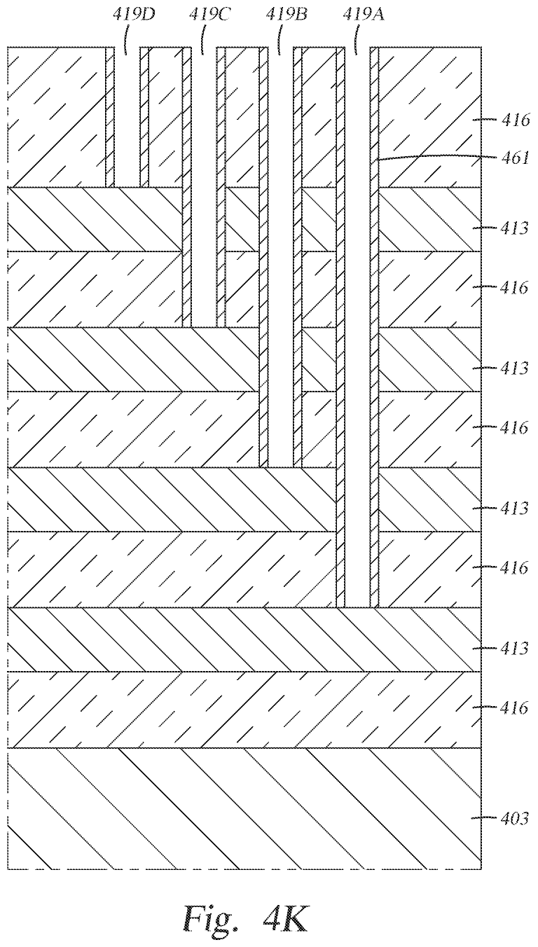

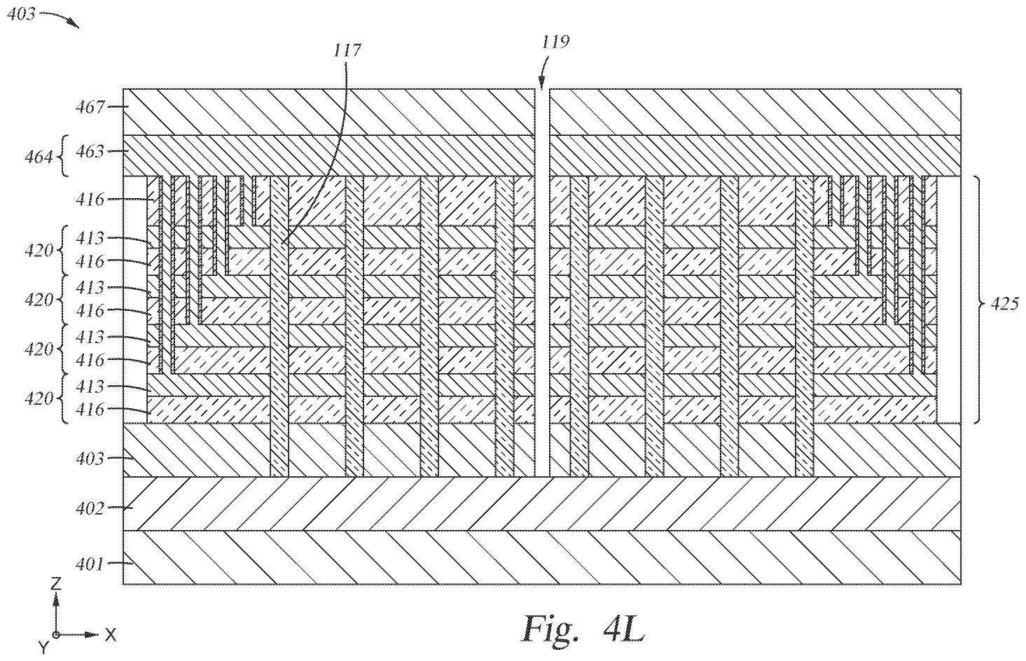

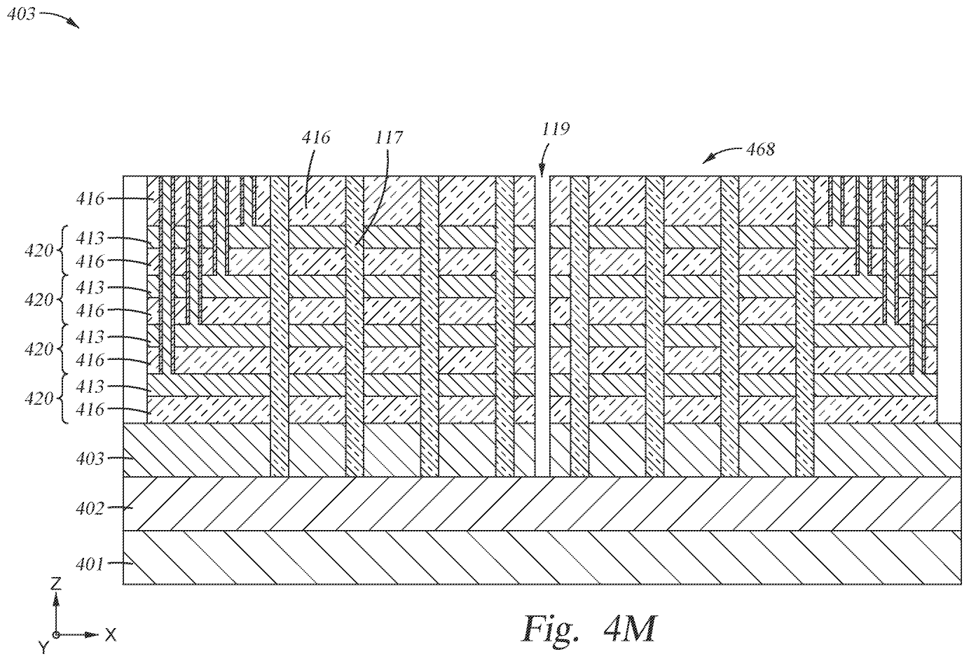

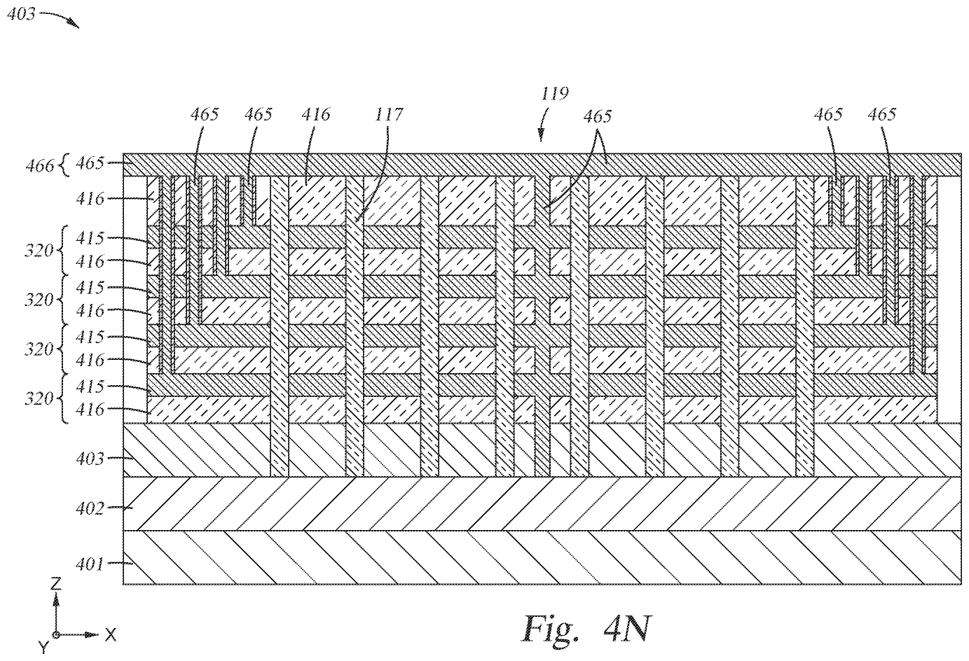

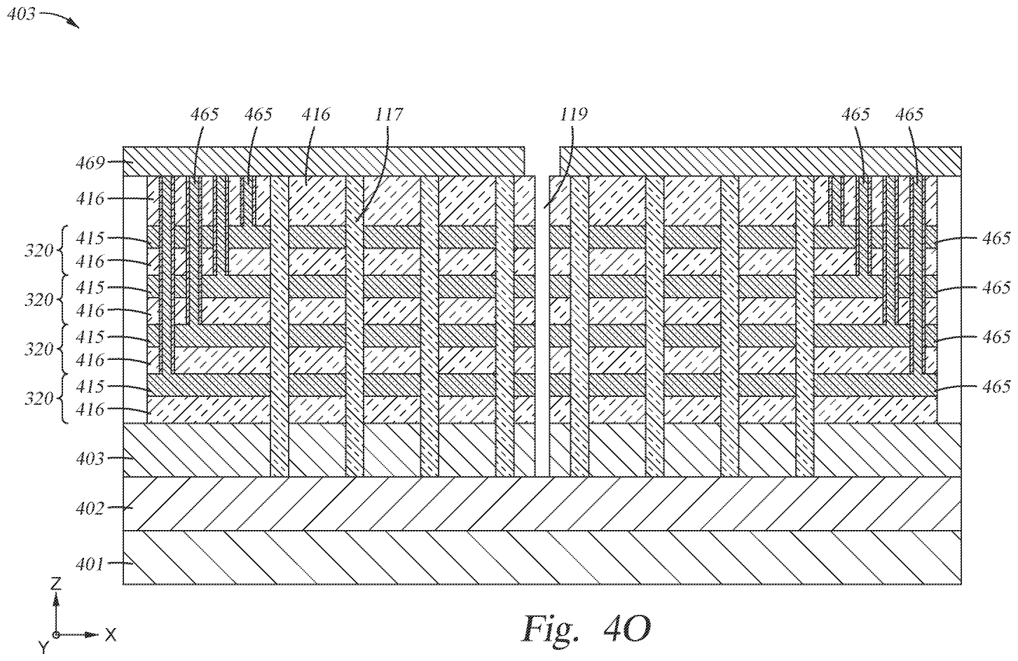

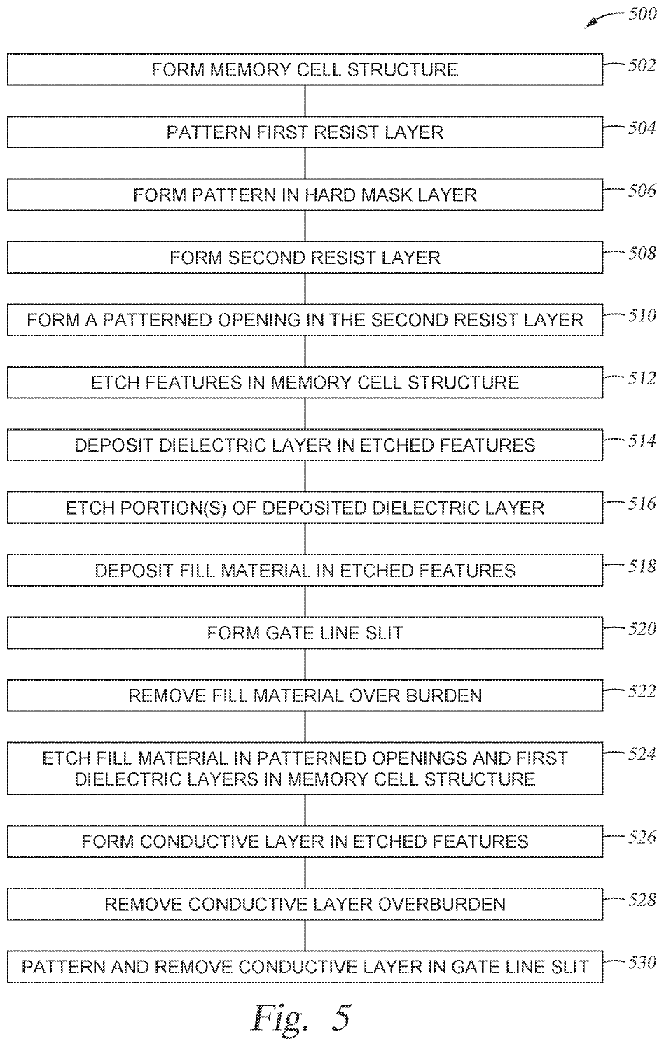

As discussed in relation to FIGS. 4A-4O and 5 below, the method of forming the 3D NAND memory structure 300 has been greatly simplified versus conventional processes that include the formation of a staircase-like structure. Moreover, the required overall lateral dimension 205 of the 3D NAND memory structure 300 is significantly decreased versus a staircase-like structure containing 3D NAND memory structure, since the lateral width 312 of the interconnect regions 310 of the 3D NAND memory structure 300 versus the lateral width 112 of the staircase regions 110 of the 3D NAND memory structure 100 can be about 4 to 5 times smaller than a conventional staircase design. The reduction in the reduced lateral width is largely due to the ability to reduce the required pitch 311 between the conductive columns 314 versus between the pitch 111 of the conductive columns 114 of the conventional 3D NAND designs, due to the reduced need to include large exposed lateral regions of the staircase steps to assure that the etched openings used to form the conductive columns 114 will reliably land on the staircase features after processing. The configurations disclosed herein also have much less stringent requirements regarding the need to align the openings used to form the conductive columns 314 to the word line layers 415 in the design(s) disclosed herein versus the word line layers 115 found in a conventional 3D NAND design. Moreover, the manufacturing processes used to form the interconnect regions 310 are much less complex, which will improve device yield and greatly reduce the cost to form the 3D NAND memory.

FIG. 5 illustrates a method 500 for use in the manufacturing of a semiconductor device, such as forming at least part of the 3D NAND memory structure 300. FIGS. 4A-4O are schematic side cross-sectional views of portions of a 3D NAND memory structure during one or more of the activities illustrated in FIG. 5, according to one or more of the embodiments described herein. FIGS. 4B-4K are close-up schematic side cross-sectional views of a portion of a memory structure 400 illustrated in FIG. 4A during one or more of the activities illustrated in FIG. 5.

The method 500 starts at activity 502 with the formation of the basic building blocks of a 3D NAND memory structure on the surface of a substrate 401, as shown in FIG. 4A. For ease of discussion, the starting basic building blocks of the 3D NAND memory structure, will be referred to herein as a memory structure 400, which essentially includes an etch stop layer 402, a common source line layer (CSL) 403 and a plurality of alternating layers 425 disposed on a surface of the substrate 401. The plurality of alternating layers 425 include a series of alternating layers of a first dielectric material 413 and a second dielectric material 416. In some embodiments, the plurality of alternating layers 425 comprise an ON stack of layers in which the first dielectric material 413 is a nitride material (e.g., silicon nitride (SiNₓ)) and the second dielectric material 416 is an oxide material (e.g., SiOx). In some embodiments, the plurality of alternating layers 425 comprise an OP stack of layers in which the first dielectric material 413 is a silicon material (e.g., polysilicon) and the second dielectric material 416 is an oxide material (e.g., SiO2). The substrate 401 can be can be any suitable starting material for forming integrated circuits, such as a silicon (Si) wafer or a germanium (Ge) wafer. The semiconductor substrate 401 may include a material such as crystalline silicon (e.g., Si<100> or Si<111>), Si₃N₄, strained silicon, silicon germanium, doped or undoped poly-silicon (poly-Si), doped or undoped silicon, patterned or non-patterned wafer, silicon on insulator (SOI), carbon-doped silicon oxides, silicon nitride, doped silicon, germanium, gallium arsenide, glass, sapphire, and the like. The substrate 401 may be a round wafer, such as a 200 mm, 300 mm, or 450 mm diameter wafer, or as a rectangular or square panel. The common source line layer (CSL) 403 and/or the etch stop layer 402 can be made from materials such as tungsten (W), silicon nitride (SiN), poly-Si, or combinations thereof.

During activity 504, a hard mask layer 406 and a first photoresist (PR) layer 407 are formed over the plurality of alternating layers 425, and patterned to form a series of patterned openings 414 therein. In one example, as shown in FIGS. 4A and 4B, the first photoresist layer 407 include an array of openings (e.g., four openings 414) that are positioned at opposing edges of the memory structure 400 and spaced a pitch distance 414A apart in a first direction (e.g., X-direction). The each of the openings 414 are positioned and sized so that subsequent etching operations using the first photoresist layer 407 can be used to enable the formation of the one or more conductive columns 314 (FIG. 3). The openings 414 in the array of openings can be formed, for example, in a rectangular or hexagonal array that is distributed across a lateral plane (i.e., X-Y plane).

In some embodiments, the hard mask layer 406 and the first photoresist (PR) layer 407 are formed over a layer of a second dielectric material 416 that is disposed on a plurality of stacked layer pairs 420, which each include the first dielectric material 413 and the second dielectric material 416. The stacked layer pairs 420 are also referred to herein as “interim stacked layer pairs,” since each of the stacked pairs contains one or more layers, or significant portions of one or more of the layers, that may not end up in the final 3D NAND device. The hard mask layer 406 may include an oxide or nitride material, such as titanium nitride (TiN), silicon nitride, aluminum oxide (AlOx), or other suitable material. The first photoresist (PR) layer 407 can be a conventional photoresist material.

Next, during activity 506, which is illustrated in FIG. 4C, an etching process is performed on the memory structure 400 to form a pattern of openings 417 in the hard mask layer 406 based on the pattern formed in the photoresist layer 407 during activity 504. The etch process can be a performed in the processing chamber 200 using a plasma etching process that selectively etches through the hard mask material 406, but stops on an underlying layer, such as the second dielectric material 416 that is disposed on the plurality of stacked layer pairs 420.

At activity 508, as illustrated in FIG. 4D, the first photoresist layer 407 is removed from the surface 417A of the hard mask layer 406 and a second photoresist layer 418 is deposited over the surface 417A of the hard mask layer 406 and openings 417 formed in the hard mask layer 406. The second photoresist layer 418 may be deposited over the surface 417A of the hard mask layer 406 and openings 417 by a spin-on process, a chemical vapor deposition (CVD) process or other similar process. The second photoresist layer 418 is formed so that it has a first thickness 421, or original thickness 421, in a second direction (i.e., Z-direction). In some embodiments, the second photoresist layer 418 includes a material that is different from the material used to from the first photoresist layer 407. In general, the second photoresist layer 418 includes a material that will be etched at a known or desired rate by the plasma chemistry formed during the subsequent etching process performed during activity 512, and need not be a photosensitive material. While not intending to limit the disclosure provided herein, in some embodiments, the second photoresist layer 418 includes an organic material, such as a polymeric material. In some embodiments, the second photoresist layer 418 includes, but is not limited to a positive photoresist, a DNQ-Novolac photoresist, a negative photoresist, an epoxy-based polymer, an off-stoichiometry thiol-enes (OSTE) polymer, a metal particle-doped polymer, a photo-enhanced particle-doped polymer, or an EUV photoresist. However, in some embodiments, the second photoresist layer 418 can include an inorganic material, such as a metal oxide such as oxide comprising tin.

At activity 510, the second photoresist layer 418 is patterned so that one or more patterned openings 419 are formed therein. The opening 419 is formed to exposed the surface 417A of the hard mask 406 and create an exposed surface 418A in the second photoresist layer 418. In one configuration, as shown in FIG. 4D, the patterned opening 419 is positioned to expose a portion of the hard mask layer 406 that is adjacent to a first opening (i.e., rightmost opening 417) of the array of openings formed in the hard mask layer 406. In another configuration, the patterned opening 419 can be formed such that it exposes a first opening of the array of openings 417 formed in the hard mask layer 406. In either configuration, as shown in FIG. 4D, at least a portion of the second photoresist layer 418 remains disposed over the surface 417A of the hard mask layer 406, and at least one or more of the openings 417 formed in the hard mask layer 406. In some embodiments, a first patterned opening 419 is formed at a first edge of the memory structure 400 and a second patterned opening 419 is formed at a second edge of the memory structure 400. In some configurations, the first edge and second edge are on opposite edges of the memory structure 400. In cases where the memory structure 400 has a rectangular shape, when viewed from a top side (i.e., −Z-direction), one or more patterned openings 419 may be formed in a desired position relative to an array of openings on each of the four sides of the memory structure 400.

Next, during activity 512, a plasma etching process is performed on the memory structure 400 to ultimately form a series of patterned openings in the alternating layers 425, such as patterned openings 419A-419D that each have a varying depth within the alternating layers 425, as shown in FIGS. 4H and 41. At the conclusion of activity 512, the formed patterned openings 419A-419D will have a depth within the alternating layers 425 such that a bottom region of each of the patterned openings is in contact with at least a portion of the first dielectric layer material 413 in a stacked layer pair 420 that is positioned at a desired depth within the alternating layers 425. The bottom region of a patterned opening can include a bottom surface and a portion of sides of the patterned opening. In one example, as schematically shown in FIGS. 4H and 41, at the completion of activity 512 the bottom surface of the patterned opening 419A is in contact with the first dielectric layer material 413 within the fourth stacked layer pair 420 of the alternating layers 425, the patterned opening 419B is in contact with the first dielectric layer material 413 within the third stacked layer pair 420 of the alternating layers 425, the patterned opening 419C is in contact with the first dielectric layer material 413 within the second stacked layer pair 420 of the alternating layers 425, and the patterned opening 419D is in contact with the first dielectric layer material 413 within the first stacked layer pair 420 of the alternating layers 425. At the conclusion of activity 512, at least N minus one (i.e., N−1) of the patterned openings (e.g., patterned openings 419A-419C) extend through at least one of the stacked layer pairs 420, where N equals the total number of stacked layer pairs 420 in the stack of alternating layers 425. In typical 3D NAND devices today, N is greater than 10, or greater than 64, or greater than 85, or greater than 100, or even greater than 150.

Referring to FIGS. 4B-4H, the plasma etching process performed during activity 512 is configured to form the patterned openings 419A-419D in the interconnect regions 310 formed on the memory structure 400 by performing the plasma etching process for a first period of time. In some embodiments, one or more process variables (e.g., process time, RF power, processing gas composition, PV waveform characteristics, pressure, etc.) of the plasma etching process are adjusted during the first period of time by use of commands sent from the controller 226 due to signals received from one or more sensors coupled to the processing chamber 200, such as the sensor assembly 290, which will be discussed further below. As illustrated in FIGS. 4E-4H, the plasma etching process performed during activity 512 will serially expose each of the mask openings 417 in the array of mask openings formed in the hard mask 406, as the position of the exposed surface 418A changes throughout the plasma etching process. Due to the differing amounts of time that the alternating layers 425 are exposed to the plasma, through each of the serially exposed mask openings 417 during the plasma etching process, the formed patterned openings 419A-D will each have a difference depth within the alternating layers 425.

FIG. 4E illustrates a portion of the memory structure 400 after a first time interval within the first period of time has elapsed. As illustrated in FIG. 4E, the plasma etching process has caused a first portion of the second photoresist layer 418 to be etched, which has caused a first opening 417 in the array of openings to be exposed, and thus allow the plasma processing gas chemistry to etch a portion of the alternating layers 425 (e.g., second dielectric layer 416) to a desired depth 441. The thickness and/or composition of the “first” second dielectric layer 416 shown in FIGS. 4E-4H, which is the top most second dielectric layer 416 positioned over the plurality of stacked layer pairs 420, may be adjusted so that the etch rate and/or time to etch through the “first” second dielectric layer 416 is similar to the average etch rate and/or etch time it takes the plasma etching process to etch through a stacked layer pair 420. However, in some embodiments, the “first” second dielectric layer 416 shown in FIGS. 4E-4H, may be removed or replaced with a third dielectric layer that has a material composition that is different from the first and second dielectric layers 413 and 416, respectively. During the first time interval the exposed surface 418A of the second photoresist layer 418 is etched laterally to a point near a second opening 417 within the array of openings. The plasma processing gas chemistry formed during the first time interval has been selected such that the amount 451 of the second photoresist layer 418 that has been etched in the lateral direction (i.e., −X-direction) is proportional to the desired amount (i.e., depth 441) that the alternating layers 425 have been etched in a vertical direction (i.e., −Z-direction). As illustrated in FIG. 4E, the plasma etching process, during the first time interval, has also removed a portion of the top surface of the second photoresist layer 418, and thus the thickness of the second photoresist layer 418 has decreased from its original thickness 421.

In general, during a portion of the plasma etching process, the amount that the second photoresist layer 418 is etched during a time interval versus the depth that the alternating layers 425 are etched during the same time interval is set by the etch selectivity of the plasma processing gas chemistry to the material(s) in the second photoresist layer 418 versus the materials in the alternating layers 425. In some embodiments, the selectivity of the plasma processing gas chemistry is adjusted during the plasma etching process so that the lateral etch rate (i.e., etch rate in X and/or Y-directions) of the second photoresist layer 418 and vertical etch rate (i.e., etch rate in Z-direction) of the alternating layers 425 are proportional to each other such that the time it takes the second photoresist layer 418 to be etched a distance of one pitch length 414A is equal to the time it takes to etch vertically through one stacked layer pair 420. For ease of discussion purposes, a plasma processing gas chemistry and process variable settings that are used to achieve this desired selectivity will be referred to herein as having or being able to achieve a desired “lateral to vertical etch selectivity.”

FIG. 4F illustrates a portion of the memory structure after a second time interval within the first period of time has elapsed. As illustrated in FIG. 4F, the plasma etching process has caused the second opening 417 in the array of openings to be exposed, and thus allow the plasma processing gas chemistry to etch a portion of the alternating layers 425 underneath the second opening to a desired depth 441, and also cause the alternating layers 425 underneath the first opening 417 to be etched an addition depth 442. During the second time interval the exposed surface 418A of the second photoresist layer 418 has also been etched to a point near a third opening 417 within the array of openings. The plasma processing gas chemistry formed during the second time interval has been selected such that the amount 452 of the second photoresist layer 418 that has been etched in the lateral direction (i.e., −X-direction) is proportional to the desired amount (i.e., depths 441 and 442) that the alternating layers 425 have been etched in a vertical direction (i.e., −Z-direction), and thus have a desired lateral to vertical etch selectivity during the second time interval. As illustrated in FIG. 4F, the plasma etching process, during the second time interval, has also removed a portion of the top surface of the second photoresist layer 418, and thus the thickness of the second photoresist layer 418 has decreased from its thickness 422 formed during the first time interval to a new thickness 423.

FIG. 4G illustrates a portion of the memory structure after a third time interval within the first period of time has elapsed. As illustrated in FIG. 4G, the plasma etching process has caused the third opening 417 in the array of openings to be exposed, and thus allow the plasma processing gas chemistry to etch a portion of the alternating layers 425 underneath the third opening to a desired depth 441, and also cause the alternating layers 425 underneath the first and second openings 417 to be etched an addition depth 442 and 443, respectively. During the third time interval the exposed surface 418A of the second photoresist layer 418 has also been etched to a point near a fourth opening 417 within the array of openings. The plasma processing gas chemistry formed during the third time interval has been selected such that the amount 453 of the second photoresist layer 418 that has been etched in the lateral direction is proportional to the desired amount (i.e., depths 441, 442 and 443) that the alternating layers 425 have been etched in a vertical direction, and thus have a desired lateral to vertical etch selectivity during the third time interval. As illustrated in FIG. 4G, the plasma etching process, during the third time interval, has also removed a portion of the top surface of the second photoresist layer 418, and thus the thickness of the second photoresist layer 418 has decreased from its thickness 423 formed during the second time interval to a new thickness 424.

FIG. 4H illustrates a portion of the memory structure after a fourth time interval within the first period of time has elapsed. As illustrated in FIG. 4H the plasma etching process has caused the fourth opening 417 in the array of openings to be exposed, and thus allow the plasma processing gas chemistry to etch a portion of the alternating layers 425 underneath the fourth opening to a desired depth 441, and also cause the alternating layers 425 underneath the first, second and third openings 417 to be etched an addition depth 442, 443 and 444, respectively. The plasma processing gas chemistry formed during the fourth time interval has been selected such that the amount 454 of the second photoresist layer 418 that has been etched in the lateral direction is proportional to the desired amount (i.e., depths 441, 442, 443 and 444) that the alternating layers 425 have been etched in a vertical direction, and thus have a desired lateral to vertical etch selectivity during the fourth time interval.

In some embodiments, at the end of activity 512, and after forming the patterned openings 419A-419D, at least a portion of the second photoresist layer 418 will remain on the hard mask layer (see FIG. 4H), and thus the original thickness 421 of the second photoresist layer 418 can be selected so that at the end of the plasma etching process a desired amount of the second resist layer 418 will remain on the surface of the hard mask layer 406. A selection of an original thickness 421 of the second photoresist layer 418 that is too thin can cause the openings 417 in the hard mask layer to be exposed too early within the plasm etching process to allow the serial formation of the patterned openings 419 in the alternating layers 425, as described herein. Also, a selection of an original thickness 421 of the second photoresist layer 418 that is too thick can make it harder to remove the second photoresist layer 418 from the hard mask layer 406 before a subsequent activity can be performed on the substrate 401.

The plasma etching process performed during activity 512, such as during the first, second, third and fourth time intervals, will include forming a plasma processing gas chemistry by delivering a processing gas composition to the processing region of the plasma processing chamber to form a chamber pressure of between 1 mT and 500 mT, wherein delivering the processing gas composition includes delivering a first process gas at a first flow rate and a second process gas at a second flow rate. The first process gas can include a first fluorocarbon-containing gas, such as at least one of C₄F₆, C₃F₆, CF₄, NF₃, C₃F₈, C₄F₈, CH₃F, CH₂F₂, SF₆, SiF₄, and WF₆, and the second process gas can include at least one of HBr, He, Ar, Xe, N₂, Kr, and O₂. The plasma processing gas chemistry can include ions, radicals and neutrals of the different gases found in the processing gas composition, wherein the amount of the ions, radicals or neutrals generated for a given processing gas composition can be adjusted by controlling the amount of RF power, amount of PV applied and chamber pressure that is maintained during processing.

The plasma etching process will also include generating and maintaining a plasma within a processing chamber by delivering an RF signal to an electrode within the processing chamber. In one embodiment, the electrode is the support bas 207, which is disposed within the substrate support assembly 236. The RF signal can include a signal provided from the RF generator 218, which is configured to establish and maintain a plasma within the processing chamber 200. The RF signal can be delivered at an RF frequency greater than about 300 KHz to an electrode, such as between about 300 kHz and 60 MHz, or even a frequency in range from about 2 MHz to about 40 MHz, such as 13.56 MHz or 40 MHz.

The plasma etching process will also include delivering a pulsed voltage (PV) waveform that is established at an electrode, which is disposed within the processing region 229 of the processing chamber 200, such as the biasing electrode 204 disposed within the substrate support 205 of the substrate support assembly 236. The substrate support 205 can be maintained at a temperature of between −80° C. and 500° C. The process of delivering the PV waveform can include delivering asymmetric PV pulses at a frequency of greater than 100 kHz, such as between 200 kHz and 800 kHz, or about 400 KHz to about 500 KHz. As discussed above, the asymmetric PV pulses can include a sheath collapse phase 282 and sheath formation phase 283 that last for a first time interval and the ion current phase 284 that lasts for a second time interval. The first time interval can be between about 100 nanoseconds (ns) and about 500 ns, such as between 200 ns and 400 ns, and the second time interval accounts for at least 80% of each cycle of the series of PV waveform, such as between 85% and 90% of each cycle. The delivery of the PV waveform can also include delivering bursts of the asymmetric nanosecond PV pulses that have a burst duty cycle that is between 1 and 99%, such as between about 50% and about 95%, and can have a burst delivery length (T_{ON}) is between about 50 μs and about 50 milliseconds (ms), such as between about 200 μs and about 5 ms. The PV waveform can include a peak-to-peak voltage that is between about 2 kilovolts (kV) and about 20 kV.

In some embodiments, during one or more portions of the first, second, third and fourth time intervals of the plasma etching process, one or more process variables are adjusted to control the depths 441-444 of the patterned openings 419A-419D and the amount the second photoresist layer 418 is etched in the lateral direction. Due to the presence and need to etch through the first dielectric layer material 413 and the second dielectric layer 416 during the first, second, third and/or fourth time intervals it may be desirable to adjust one or more of the process variables to reduce the total etching time and/or the etching rate during one or more portions of each of the first, second, third and fourth time intervals. In one example, one or more process variables may be adjusted during a first portion of the each of the time intervals to tailor the etching process to etch a silicon nitride containing material, and then one or more process variables may be adjusted during a second portion of the each of the time intervals to tailor the etching process to etch a silicon oxide containing material. In one example, the one or more process variables that are adjusted can include the plasma processing gas chemistry, time interval length, chamber pressure, RF power, and/or PV voltage waveform characteristics.

In some embodiments, one or more sensor assemblies 290 are used to detect a property of a portion of the substrate surface, such as a portion of the second photoresist layer 418, a portion of the hard mask layer 406, or a combination thereof to determine a state of the plasma etching process during one or more portions of the first, second, third and fourth time intervals and then adjust and/or control one or more aspects of the plasma etching process based on a detected property. During activity 512, a signal, which includes information regarding the detected property of the substrate surface, is provided the controller 226 so that the information can be used by a software algorithm, running within the controller 226, to determine if one or more characteristics of a plasma etching process needs to be adjusted. In one example, a detected property of a portion of the substrate surface can include the detection of a status (e.g., relative percent completion) or endpoint of portions of the plasma etching process during the first, second, third and fourth time intervals by detecting an amount of interference and/or the amount of light transmitted to and received from the second photoresist layer 418, portion of the hard mask layer 406, or a combination thereof by use of the probe 292 and sensor 291 of the sensor assembly 290. In another example, the sensor assembly 290 is configured to perform an in-situ measurement to determine a relative depth of the patterned openings 419A-419D, the thickness of the second photoresist layer 418 during the first, second, third and fourth time intervals (e.g., thicknesses 421, 422, 423, 424 and/or 425), and/or determine the position of the exposed surface 418A during first, second, third and fourth time intervals relative to the original position of the exposed surface 418A, which was formed during activity 510. The in-situ measurement can include the use of an interferometric technique that is performed at wavelengths in a spectral range of between 200 nanometers (nm) and 1700 nm, such as between 200 nm and 800 nm. Therefore, during a plasma etching process, the controller 226 can receive a signal from the sensor 291, which is positioned to detect a property of a surface of the substrate, wherein the signal includes information regarding the detected property of the substrate surface. The software running on the controller 226 can then determine that one or more characteristics of a plasma etching process needs to be adjusted based on the information received in the signal. The controller 226 can then send commands to one or more of the process chamber components to adjust one or more of the process variables, such as processing time, RF power level, processing gas composition (e.g., relative amount of the first process gas or second process gas), PV waveform characteristics, chamber pressure, or other desirable process variable, based on the determined characteristic of the plasma etching process that needs to be adjusted.

Next, during activity 514, the remaining portions of the second photoresist layer 418 and hard mask layer 406 are removed, and the substrate is cleaned using conventional processes, as shown in FIG. 4I. Also, during activity 514 a dielectric layer is deposited on the memory structure 400 so as form a dielectric layer 461 thereover and within the patterned openings 419A-419D, as shown in FIG. 4J. The dielectric layer 461 is used in a formed 3D NAND device to isolate the conductive portion (e.g., W material) of each conductive column 314 (FIG. 3) from the conductive material 465 used to form the word line layers 415 so that each conductive column 314 can pass-through a word line layer 415 without making an electrical connection. In one example, the conductive column 314 that is to be formed in the opening 419A will be prevented from making electrical contact to the word line layers 415 in the first, second and third stacked layer pairs 320 (FIGS. 3 and 4O), counting from the top down, due to the presence of the dielectric layer 461 lining the vertical surface of the patterned opening 419A. The dielectric layer 461 can be formed using an atomic layer deposition (ALD), plasma enhanced ALD process (PEALD), chemical vapor deposition (CVD) process, plasma enhanced CVD process (PECVD) or other conformal deposition process to form a dielectric layer that can include a silicon oxide (SiOx), silicon (Si) or other dielectric material that will not be substantially etched during a process that is used to etch the first dielectric material 413. The dielectric layer 461 may have a thickness of between 10 angstroms (Å) and 5,000 Å, such as between 10 Å and 1000 Å.

During activity 516, the dielectric layer 461 is removed from the field region (top surface) and bottom portion of the patterned openings 419A-419D of the memory structure 400. The process of removing the dielectric layer 461 from the field region and bottom portion of the patterned openings 419A-419D can be performed by use a sputter etching process, dry etching process or other similar process. In some embodiments, a sputter etching process is performed in an ALD, PEALD, CVD, or PECVD process chamber, after the dielectric layer 461 is deposited on the memory structure 400 therein, by generating a plasma and biasing the substrate 101 so that ions formed in the plasma will tend to selectively etch the field region and bottom portion of the patterned openings 419A-419D.

Next, during activity 518, as shown in FIG. 4L, the patterned openings 419A-419D formed in the memory structure 400 are filled with a fill material 463 that is at least similar to and/or essentially the same as the material found in the first dielectric material layer 413. In one embodiment, the fill material is a silicon nitride (SiNx) material that is formed by use of a conventional, ALD, PEALD, CVD, PECVD, or physical vapor deposition (PVD) process. After filling the patterned openings 419A-419D an overburden layer 464, which contains the fill material 463, is formed on the field region of the memory structure 400.

Next, during activity 520, as also shown in FIG. 4L, a gate slit line 119 is formed through the memory structure 400. The process of forming the gate slit line 119 will include depositing a third photoresist layer 467, patterning the third photoresist layer 467 to form an opening in the third photoresist layer 467, and then performing one or more conventional dry etching processes to etch through the over burden layer 464, alternating layers 425, and common source line layer (CSL) 103 to form a separation between regions of the memory structure 425.

Next, during activity 522, as shown in FIG. 4M, the third photoresist layer 467 and over burden layer 464 are removed, and the substrate is optionally cleaned using one or more conventional processes, to expose a top surface 468 of the memory structure 400. In some embodiments, the over burden layer 464 is removed by use of a conventional chemical mechanical polishing (CMP) process or other similar process.

Next, during activity 524, a selective etching process is performed on the memory structure 400 to remove the material(s) formed within the patterned openings 419A-419D and first dielectric layers 413. The process of removing the material within these features can be formed by use of one or more conventional etching processes used in the formation 3D NAND structures today. In one example, an isotropic etch process is performed to selectively remove the material(s) formed within the patterned openings 419A-419D and the first dielectric layers 413 relative to the second dielectric layer 416 and third dielectric layer 461. In some examples the selective etching process includes delivering nitrogen trifluoride (NF₃), a mixture of nitrogen trifluoride and helium (He) or a similar process chemistry to the memory structure 400 to remove the desired materials.

Next, during activity 526, as shown in FIG. 4N, a conductive material 465 is formed in the spaces that were created during activities 520 and 522. The conductive material 465, which is used to form the conductive columns 314 (FIG. 3), is electrically isolated from the one or more stacked layer pairs 320 that the formed conductive column 314 extends through due to the presence of the dielectric layer 461. In some embodiments, the conductive material 465 includes at least one of tungsten (W), platinum (Pt), titanium (Ti), ruthenium (Ru), cobalt (Co), and silicon (Si) that formed by use of a conventional ALD, PEALD, CVD, or PECVD process. In one example, the conductive material 465 includes tungsten (W) that is formed by use of a conventional ALD process. During the process of filling the patterned openings 419A-419D an overburden layer 466 is formed on the field region of the memory structure 400.

Next, during activity 528, the overburden layer 466 is removed, and the substrate is optionally cleaned using one or more conventional processes. In some embodiments, the over burden layer 466 is removed by use of a conventional chemical mechanical polishing (CMP) process or other similar process.

Next, during activity 530, as also shown in FIG. 4O, the gate slit line 119 is reformed through the memory structure 400. The process of reforming the gate slit line 119 will include depositing a fourth photoresist layer 469, patterning the fourth photoresist layer 469 to form an opening in the fourth photo resist layer 469, and then performing one or more conventional dry etching processes to etch through the conductive material 465 formed in the gate slit line space that was originally created during activity 526, to form a separation between regions of the memory structure 425.

After performing the activities of method 500 on the memory structure 400, additional conventional processing steps will be performed on the memory structure 400 to complete the formation of a functioning 3D NAND device.

The methods, apparatus and portions of the 3D NAND device structure(s) described herein can be used to form a 3D NAND memory structure that has a reduced size, lower manufacturing cost, and improved reliability versus the conventional 3D NAND processing techniques known today. Embodiments of the disclosure provided herein include an apparatus and method of forming an improved three-dimension (3D) NAND memory structure by use of a less complex processing sequence versus the conventional 3D NAND processing techniques known today. It is believed that the precise control of the plasma ion density, plasma sheath characteristics and ion energy, in combination with the use of a desirable dry etch chemistries, which are described herein, can be beneficially used to cause an increase in etch selectivity and improve etch process result used to form the novel 3D NAND memory structures disclosed herein. Moreover, by use of one or more of the methods described herein, etch selectivity and improved etch process results can be further achieved by monitoring and controlling the various aspects of the plasma etching processes, as described herein.

While the foregoing is directed to embodiments of the present disclosure, other and further embodiments of the disclosure may be devised without departing from the basic scope thereof, and the scope thereof is determined by the claims that follow.

We claim:

1. A method of forming a non-volatile memory device, comprising:
etching a plurality of alternating layers formed over a surface of a substrate, wherein the alternating layers comprises a first layer and a second layer that are stacked in a vertical direction, and etching the plurality of layers comprises:
(a) delivering a processing gas composition to a processing region of a process chamber;
(b) forming a plasma in the processing region of the process chamber, wherein the plasma comprises the processing gas composition; and
(c) establishing a voltage waveform at an electrode that is positioned a distance from a substrate supporting surface of a substrate support that is disposed within a processing region of a processing chamber while the plasma is formed over a substrate that is positioned on the substrate supporting surface,
wherein the substrate comprises:
a hard mask layer disposed over the first layer and the second layer of the plurality of alternating layers, wherein the first layer comprises a first material and the second layer comprises a second material that is different from the first material;
an array of mask openings formed in the hard mask layer that are aligned in a first pitch direction, and have a pitch length in the first pitch direction between adjacent mask openings in the array of mask openings; and
a first photoresist layer disposed over the hard mask layer and over two or more of the mask openings in the array of openings, wherein at least one of the mask openings in the array of openings is exposed to the formed plasma through an opening formed in the first photoresist layer,
wherein the processing gas composition is selected so that the formed plasma causes
the opening formed in the first photoresist layer to increase in size in the first pitch direction a length that equal to the pitch length during a first time interval, and
simultaneously etch through a thickness of the first layer and the second layer during the first time interval.

2. The method of claim 1, wherein the first material comprises silicon and nitrogen, and the second material comprises silicon and oxygen.

3. The method of claim 1, wherein the first material comprises silicon and nitrogen, and the second material comprises polysilicon.

4. The method of claim 1, wherein the first photoresist layer comprises a DNQ-Novolac photoresist, an epoxy-based polymer, or an off-stoichiometry thiol-enes (OSTE) polymer.

5. The method of claim 1, wherein the voltage waveform comprises:
a series of pulses that each have a first time interval that extends for 200 ns to 400 ns, and a second time interval accounts for at least 80% of each pulse cycle of the series of pulses, and
each pulse in the series of pulses has a peak-to-peak voltage that is between about 2 kV and 20 kV.

6. The method of claim 1, wherein the processing gas composition comprises at least one of C₄F₆, C₃F₆, CF₄, NF₃, C₃F₈, C₄F₈, CH₃F, CH₂F₂, SF₆, SiF₄, and WF₆, and at least one of HBr, He, Ar, Xe, N₂, Kr, and O₂.

7. The method of claim 1, wherein the alternating layers comprise a plurality of the first layers and the second layers that are alternately stacked in a vertical direction, and the method further comprises performing (a), (b) and (c) until
the first photoresist layer positioned over the two or more mask openings in the array of mask openings is removed, and
patterned openings formed in the alternating layers through each of the mask openings have a bottom surface that has a differing depth within the alternating layers, wherein the bottom surface of each of the patterned openings have a first end that is contact with a portion of a first layer of the plurality of the second layers.

8. The method of claim 7, further comprising:
depositing a dielectric layer over the surfaces of the patterned openings formed in the alternating layers, and
removing at least a portion of the deposited dielectric layer from the bottom surface of each of the patterned openings formed in the alternating layers.

9. The method of claim 8, further comprising, after removing at least a portion of the deposited dielectric layer from the bottom surface of each of the patterned openings formed in the alternating layers, filling the patterned openings formed in the alternating layers with the first material.

10. The method of claim 9, further comprising:
etching the filled patterned openings and each of the first layers to remove the first material from the filled patterned openings and each of the first layers to form an opening that extends through the patterned openings and through at least a portion of the first layers; and
filling the etched patterned openings and etched first layers with a conductive material, wherein the conductive material comprises at least one of tungsten, platinum, titanium, ruthenium, and silicon.

11. The method of claim 1, further comprising:
receiving, by a controller, a signal from a sensor that is positioned to detect a property of a surface of the substrate while etching the plurality of layers, wherein the signal includes information regarding the detected property of the substrate surface; and
determining, by the controller, that one or more characteristics of a plasma etching process needs to be adjusted based on the received signal.

12. A method of forming a non-volatile memory device, comprising:
positioning a substrate on a surface of a substrate support that is disposed within a processing region of a processing chamber, wherein the substrate comprises:
a hard mask layer disposed over a plurality of alternating layers formed over a surface of the substrate, wherein the alternating layers comprises a first layer and a second layer that are stacked in a vertical direction;
an array of mask openings formed in the hard mask layer that are aligned in a first pitch direction, and have a pitch length in the first pitch direction between adjacent mask openings in the array of openings; and
a first photoresist layer disposed over the hard mask layer and over two or more of the mask openings in the array of mask openings, and comprises an opening in the first photoresist layer that has an exposed surface, wherein the opening is positioned to expose a first mask opening of the array of mask openings or expose a portion of the hard mask layer adjacent to the first mask opening of the array of mask openings;
delivering a processing gas composition to the processing region of the process chamber;
etching a plurality of alternating layers formed over the surface of a substrate, wherein etching the plurality of layers comprises:
forming a plasma in the processing region of the process chamber, wherein the plasma comprise the processing gas composition and the plasma is formed over the first photoresist layer and the opening formed therein,
wherein etching the plurality of alternating layers causes the first photoresist layer to be etched so that each of the mask openings in the array of mask openings are serially exposed to the formed plasma during the process of etching the plurality of alternating layers, and causes portions of the alternating layers disposed below the serially exposed mask openings to form patterned openings that each have a differing depth within the alternating layers.

13. The method of claim 12, wherein a bottom surface of each of the patterned openings have a first end that is contact with a portion of a first layer of the plurality of the second layers.

14. The method of claim 12, further comprising establishing a voltage waveform at an electrode that is positioned a distance from the substrate supporting surface while the plasma is formed over the first photoresist layer and the opening formed therein.

15. A non-volatile memory device, comprising:
a plurality of alternating layers, wherein the plurality of alternating layers comprise:
a plurality of stacked layer pairs that each comprise a first layer that comprises a first material and a second layer that comprises a second material which is different from the first material, wherein the plurality of stacked layer pairs are stacked in a first direction and comprise N stacked layer pairs, and N is greater than 10; and
a plurality of conductive columns, wherein
each of the conductive columns are aligned in a first pitch direction, and are separated in the first pitch direction by a pitch length,
N−1 of the conductive columns extend through one or more stacked layer pairs, and
each of the conductive columns comprises a dielectric layer that is disposed between a conductive material disposed within the conductive column and the layers of the one or more stacked layer pairs that the conductive column extends through, wherein a voltage is applied to the conductive material of the conductive column during operation of the non-volatile memory device,
wherein the first material and the conductive material each essentially comprise the same material.
